(19) United States
(12) Patent Application Publication
(10) Pub. No.: US 2022/0171894 A1
(43) Pub. Date: Jun. 2, 2022

(54) CAD LOCATOR FOR SITE NAVIGATION

(71) Applicant: KPR Publishing LLC, Elm Springs, AR (US)

(72) Inventor: Phillip May, Springdale, AR (US)

(21) Appl. No.: 17/539,959

(22) Filed: Dec. 1, 2021

Related U.S. Application Data
(60) Provisional application No. 63/120,388, filed on Dec. 2, 2020.

(51) Int. Cl. G06F 30/13

(52) U.S. Cl. CPC G06F 30/13

(57) ABSTRACT

Collecting survey data for a survey site. A method includes at a mobile device, a mobile device including location tracking hardware, receiving an overlay file created from a CAD file for the survey site. The overlay file is overlaid on a location tracking enabled map at the mobile device. Location information is determined for the mobile device using the location tracking hardware. Location information of a user correlated with data in the overlay file is displayed. Survey information is collected for the survey site, the collected survey information included location information correlated to data in the overlay file or the CAD file.

### CROSS-REFERENCE TO RELATED APPLICATIONS

This application claims the benefit of and priority to U.S. Provisional Patent Application Ser. No. 63/120,388 filed on Dec. 2, 2020, and entitled “CAD LOCATOR FOR SITE NAVIGATION,” and which application is expressly incorporated herein by reference in its entirety.

### BACKGROUND

### Background and Relevant Art

In the field of surveying, modern surveyors use GPS real-time kinematic devices to provide highly accurate surveying of sites by providing data from such systems to a data collector. Indeed, surveying can be done with centimeter level accuracy using such devices. Typically, these devices comprise a set of devices including a base station (commonly referred to as a “base”) having a receiver that is placed in a known and fixed location. These devices also include a matching rover receiver. Both of these devices use the GPS system to obtain the aforementioned high accuracy. However, these devices can be incredibly expensive ranging anywhere from $20,000-$50,000. Thus, it would be useful if a surveying system could be created which can collect surveying data in a more economical fashion.

The subject matter claimed herein is not limited to embodiments that solve any disadvantages or that operate only in environments such as those described above. Rather, this background is only provided to illustrate one exemplary technology area where some embodiments described herein may be practiced.

### BRIEF SUMMARY

One embodiment illustrated herein includes a method that may be practiced in a surveying environment. The method includes acts for collecting survey data for a survey site. The method includes at a mobile device, the mobile device including a GPS receiver and/or other location tracking hardware such as hardware that tracks pings from cell towers, hardware for detecting wi-fi networks having a known location, hardware for RFID tracking, or other tracking, receiving an overlay file created from a CAD file for the survey site. The overlay file is overlaid on a location tracking enabled map at the mobile device. Location information is determined for the mobile device using the location identifying hardware. Location information of a user correlated with data in the overlay file is displayed. Survey information is collected for the survey site, the collected survey information includes location information correlated to data in the overlay file or the CAD file.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 illustrates a mobile device-based survey system and operation of same;

FIG. 2 illustrates additional details of a mobile device implementing an app for a survey system;

FIGS. 3-20 illustrate various screens on a user interface for an app implementing a CAD file-based overlay onto a location tracking enabled map on a mobile device; and

FIG. 21 illustrates a method of collecting survey data using a mobile device equipped with location tracking hardware.

### DETAILED DESCRIPTION

Some embodiments illustrated herein are directed to a mobile device, such as a smart cellular telephone or tablet, implementation which utilizes location tracking hardware included in the smart cellular telephone, along with existing mapping software to implement an inexpensive surveying data collection system. In particular, embodiments may implement an app on a smart phone that can overlay computer aided design (CAD) data onto a map and/or mapping application including location tracking functionality to allow positional surveying data to be collected with respect to corresponding locations of the CAD data.

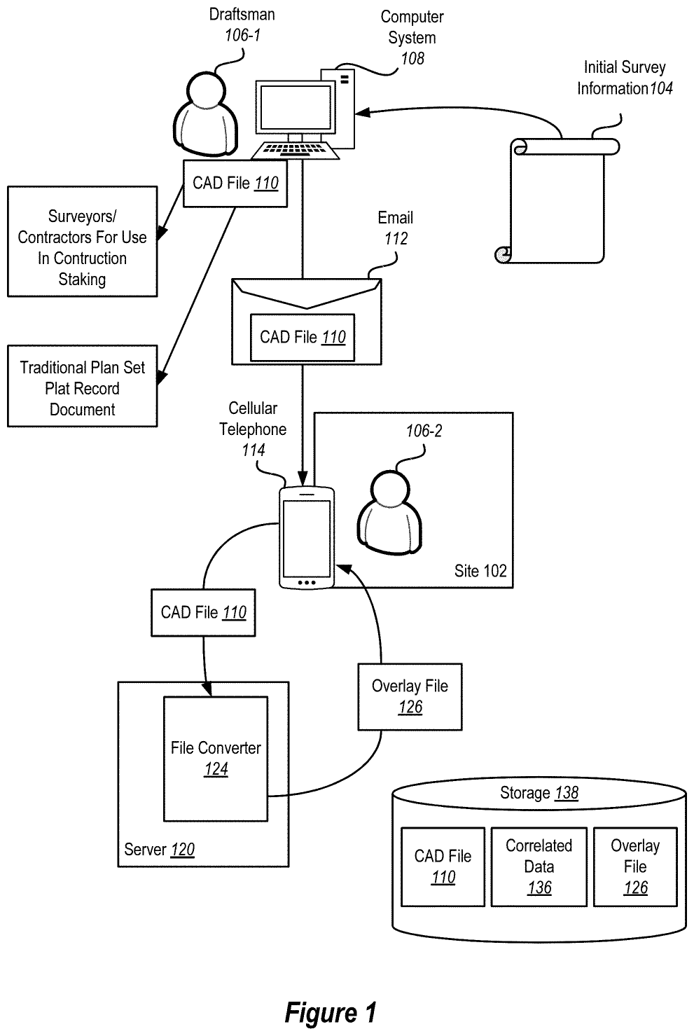

Referring now to FIG. 1, an example is illustrated. In the example illustrated in FIG. 1, survey operations for a site 102 may need to be performed. Such operations may include, for example, calculation of grade, setting of control points, and the like.

The following illustrates various actions on how this occurs. A state plane projection may be obtained for the site 102. The state plane projection is a standardized survey zone for the particular site that takes into account various aspects such as curvature the earth and other aspects for a particular geographic location. Thus, this information is used to create initial survey information 104, which may include survey field measurements and identify the location and other survey information for the site 102. This initial survey information 104 is used by a draftsman 106-1 using a computer system 108 to create a CAD file 110. That is, a canvas can be created at the computer system using a CAD software program. The canvas is particular to the site 102 by virtue of the canvas being initialized with the initial survey information 104, including location information for the site 102. The draftsman 106-1 can then enter data on the canvas including various building drawings, road and sidewalk structures, or other design aspects to create the CAD file 110. For example, in one embodiment, the CAD file may be a DXF file which is a common format for CAD systems. This CAD file 110 is typically used by surveyors and contractors for use in construction staking. Alternatively, or additionally, the CAD file 110 can be used in creating traditional plan set plat record documents.

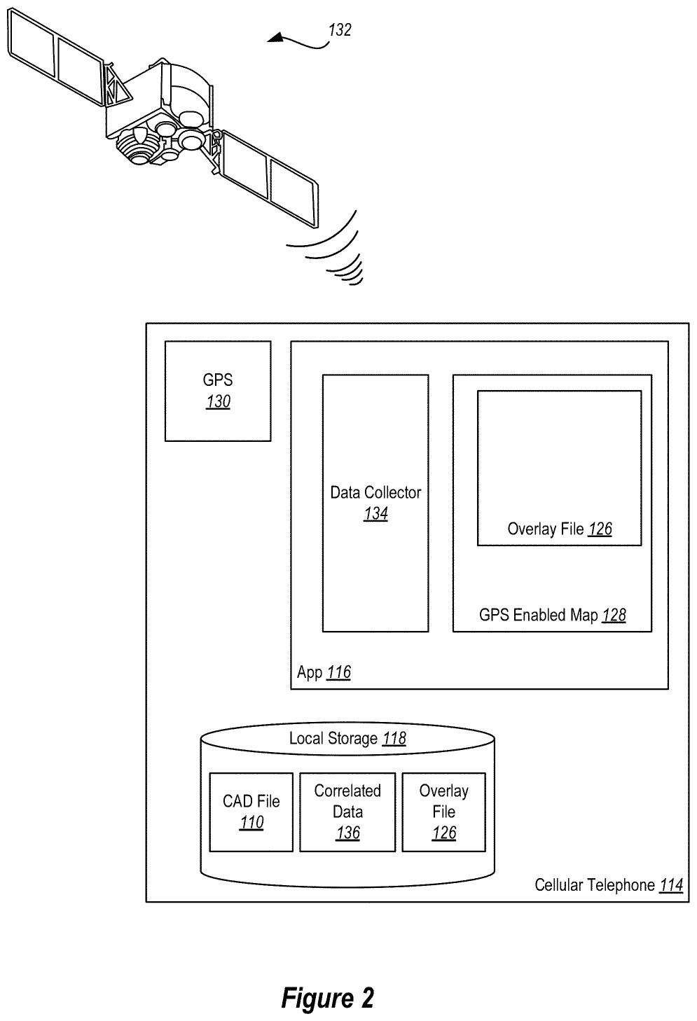

FIG. 1 illustrates that the CAD file 110 can be sent in an email 112 to a second user 106-2 through their cellular telephone 114. Note that while a cellular telephone is illustrated, it should be appreciated that other mobile devices having network and location tracking hardware may be used in alternative embodiments. At the cellular telephone 114, the user 106-2 can cause the CAD file 110 to be stored in a local storage 118 (see FIG. 2) of the cellular telephone 114. The cellular telephone 114 may further include an app 116 that is configured to be used in performing the survey data collection functionality. In particular, the app 116 is able to obtain the CAD file 110 off of the local storage 118 of the cellular telephone 114 and to send the CAD file 110 to a server 120 (see FIG. 1). The server 120 includes a file converter 124 that is able to convert the CAD file 110 to an overlay file 126. For example, in some embodiments the converter 124 may be based on the Geospatial Data Abstraction (GDAL) library available from the Open-Source Geospatial Foundation. For example, the converter may be configured to convert DXF files to KML files, which can be overlaid on various mapping applications, such as Google Maps. Thus, in the present example, the overlay file 126 is a KML file. Note that in some embodiments, the file converter 124 is able to receive as input multiple different files to create a single overlay file 126. For example, in some embodiments, the file converter may receive multiple CAD files, one or more maps with encoded GIS data or other files, which can be used in various combinations to create the overlay file 126.

FIG. 1 further illustrates that the server 120 can send the overlay file 126 back to the cellular telephone 114 where it is stored on local storage 118 and used by the app 116 (See also FIG. 2). Note that the local storage 118 may be one or more of a number of different types of storage. For example, the local storage 118 may be persistent storage, such as internal storage and/or removable storage such as SD cards and the like. Alternatively, or additionally, the local storage 118 may be RAM in the cellular telephone 114. The app 116 will retrieve the overlay file 126 and overlay it on a location tracking enabled map 128. In particular, the initial survey information 104 used to create the CAD file 110 includes sufficient information to correlate the overlay file 126 with coordinates on the location tracking enabled map 128. The location tracking enabled map is an application that obtains data from location tracking hardware 130, which obtains location tracking data from GPS satellites 132, or other location hardware, such that an accurate location can be obtained for the cellular telephone 114, such that the location can be correlated to locations in the location tracking enabled map 128 and the locations in the overlay file 12. The app 116 is then able to collect survey data using a data collector application 134 as the user 106-2 surveys the site 102. In particular, as the user 106-2 moves about the site 102, location tracking data can be correlated to information in the overlay file 126. That is, control points, grade information, etc. can be generated and correlated to the data in the overlay file 126, and/or the cad file 110. In some embodiments, the app 116 is able to add additional data directly to the CAD file 110 as appropriate. For example, the app 116 may receive information from the server 120 that is able to correlate portions of data in the overlay file 126 to portions of data in the CAD file 110. In this way, data can be collected and correlated to data in the overlay file 126 or correlated to data in the CAD file 110. The CAD file can be updated by the app 116 based on the collected data collected by the data collector 134. In some embodiments, these updates occur on the cellular telephone 114.

As such, the app 116 can store in the local storage 118 this correlation between location tracking hardware obtained data and data on the overlay file 126 and/or CAD file 110. In particular, correlated data 136 can be collected and used in a fashion similar to data collected by traditional base and rover systems.

Note that in some embodiments, the CAD file 110 may be sent to the cellular telephone 114 using other types of communication other than email.

Note that while FIG. 1 illustrates that the CAD file 110 is sent from the computer system 108 to the cellular telephone 114, in other embodiments, the CAD file 110 may be sent via email or other communication means directly to the server 120 thus bypassing the cellular telephone 114. Nonetheless, the server will convert the CAD file 110 to an overlay file 126 and send the overlay file to the cellular telephone 114.

Note that various different types of CAD files may be used including one or more of DXF files DWG files, LN3 files, PLN, SVL files, etc. Also note that other types of overlay files may be implemented such as .csv, .txt, .xyz, .asc, .dat, .nez, .auf, .pf, .pfn, .pts, etc. Further, various types of overlay files may be produced, such as .KML, .KMZ, etc.

Note that while the example illustrated in FIG. 1 illustrates that various pieces of data can be stored at the local storage 118, it should be appreciated that in other embodiments the data can be stored, alternatively or additionally, in other storage locations as illustrated by storage 138, such as for example cloud-based storage. Thus, for example, in some embodiments, the CAD file 110 may never actually reside on the cellular telephone 114, but rather may be stored in a cloud-based storage and sent from the cloud-based storage to the server 120. Alternatively, the CAD file 110 may only be downloaded from the cloud-based storage when the app 116 obtains the CAD file 110 from the cloud-based storage to send it to the server 120. Alternatively, or additionally, data such as CAD files, overlay files, and correlated data may be stored both at the cellular telephone 114 and the external storage 138. In some embodiments, a user may wish to choose to delete CAD files and/or correlated data from the cellular telephone 114 once the data has been stored on external storage 138.

Further, in some embodiments, the location tracking enabled map 128 is configured to use latitude and longitude location information. However, some embodiments of the app 116 may be able to convert latitude and longitude information received by the location tracking enabled map 128 to northing and easting coordinates that can be displayed to the user. In particular, this conversion can be done in real time as latitude and longitude information is received such that northing and easting coordinates are displayed to the user accurately representing the location of the user with respect to the overlay file 126 in those northing and easting coordinates.

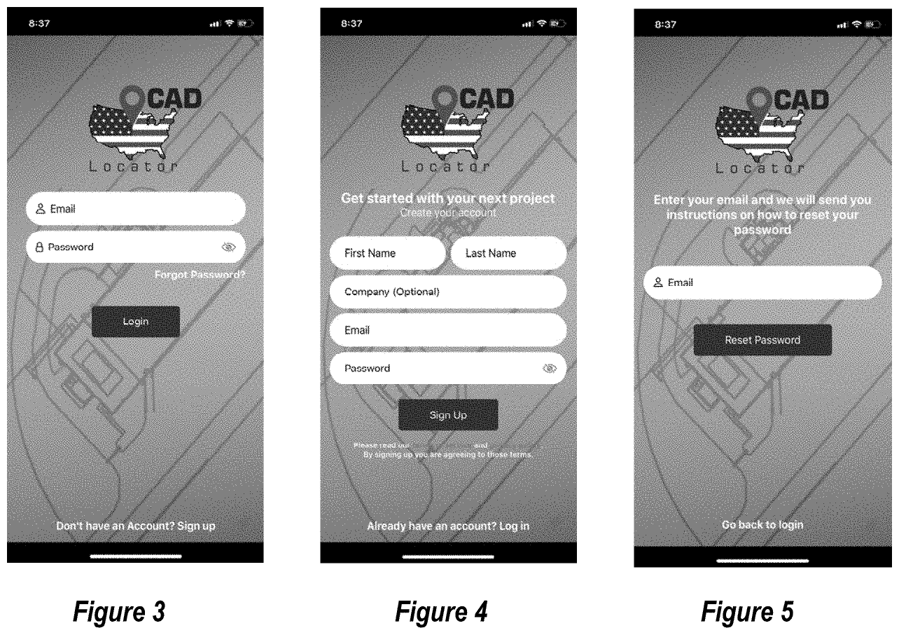

Referring now to FIGS. 3-20, various user interface screens are shown that can be displayed by the app 116.

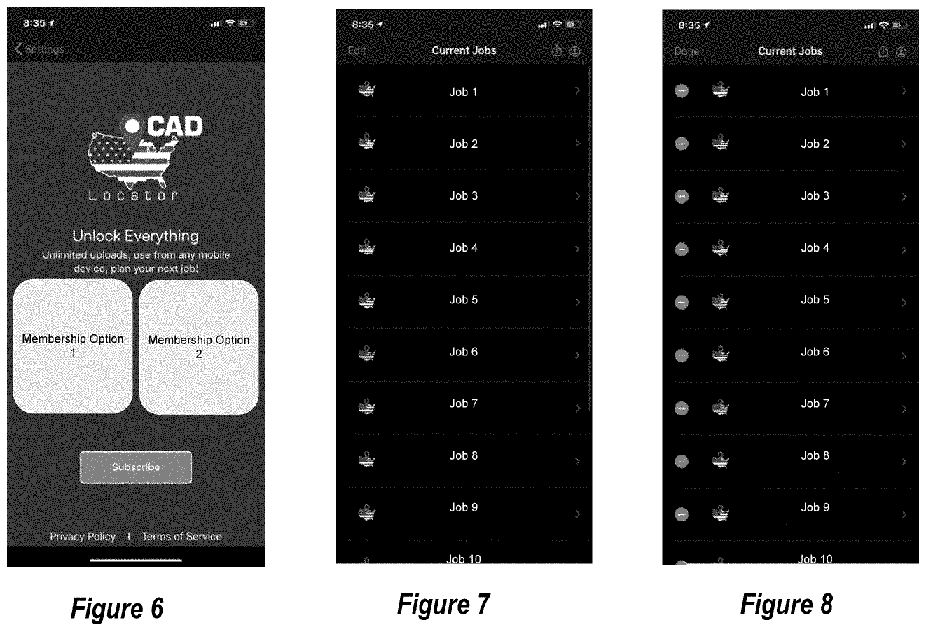

FIG. 3 illustrates a login screen where the user can enter various credentials to log into an account associated with the app 116 to allow a user to access resources on the server 120. FIG. 4 illustrates an example of a screen where the user can register a new account to access resources on the server 120. FIG. 5 illustrates an example of a password reset screen that can be used to obtain access to the app 116 and the resources on the server 120 when a user has forgotten their password, a password has become compromised, or for other reasons. FIG. 6 illustrates a screen providing a user with options to subscribe to a service allowing access to the app 116 and services on the server 120.

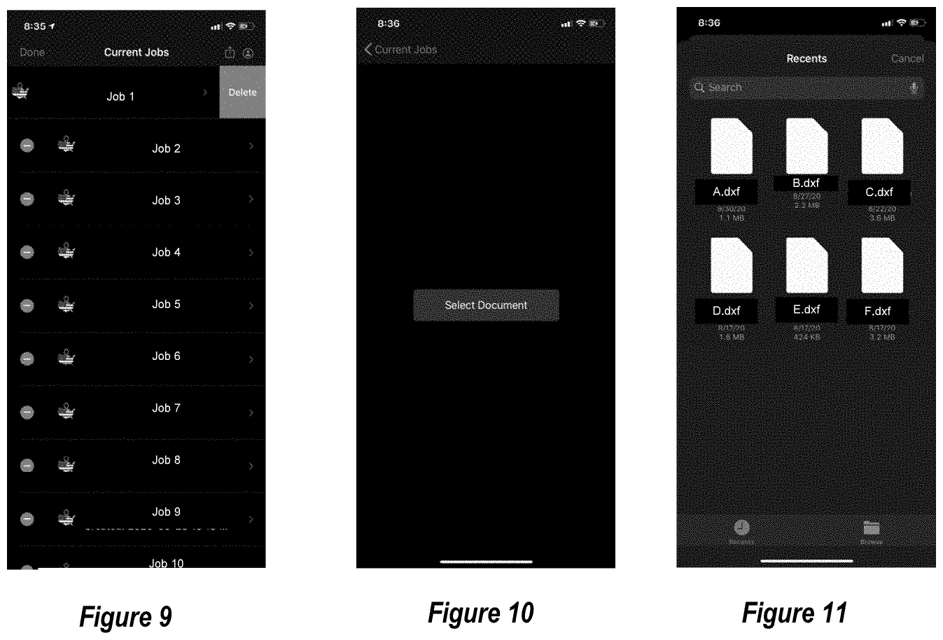

Once a user has logged on to the app 116, the user is able to perform functionality as previously described herein. With reference to FIG. 7, several current jobs are illustrated that have been stored by the app 116. Each of these jobs is associated with one or more of a CAD file, an overlay file, and/or collected data for a site. Note that as illustrated in FIGS. 8 and 9, users can manage current jobs such as for example by deleting jobs from the cellular telephone 114.

Moving now to FIG. 10, a user interface is illustrated that allows a user to select a document, such as a CAD file 110, stored on local storage 118 of the cellular telephone 114. For example, as illustrated in FIG. 11, several documents are shown that are stored on the local storage 118 of the cellular telephone. The user can select one of these documents to send to the server 120 to obtain the overlay file 126.

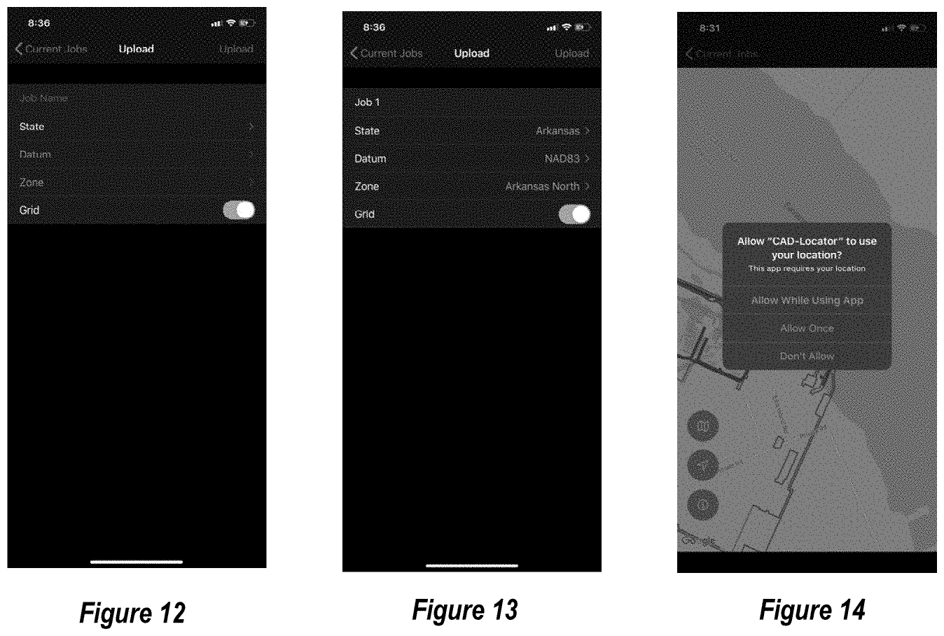

Once the user has obtained the overlay file 126, the overlay file can be overlaid on a location tracking enabled map 128. However, as illustrated in FIGS. 12 and 13, additional functionality can be utilized. For example, in some embodiments, as illustrated in FIG. 12 a user can select which type of projection is displayed in the app 116 when the overlay file 126 is overlaid onto the location tracking enabled map 128. For example, a user can select a grid projection as shown in FIG. 13. Alternatively, a user could select a surface projection. If the user selects surface projection, the user can also input an appropriate correction factor. Further, as illustrated in FIG. 13, the app 116 can display information obtained from the initial survey information 104 for a particular overlay file 126. For example, in FIG. 13, the app 116 displays on the output of the cellular telephone 114 the job name for a selected job, a state where a job will be performed, a geodetic datum used for the job, and a particular zone for the geodetic datum.

Referring now to FIG. 14, a user may be prompted to allow location services to be used while using the app 116 to allow data to be collected and to indicate locations of the user correlated with data in the overlay file 126 corresponding to the site 102.

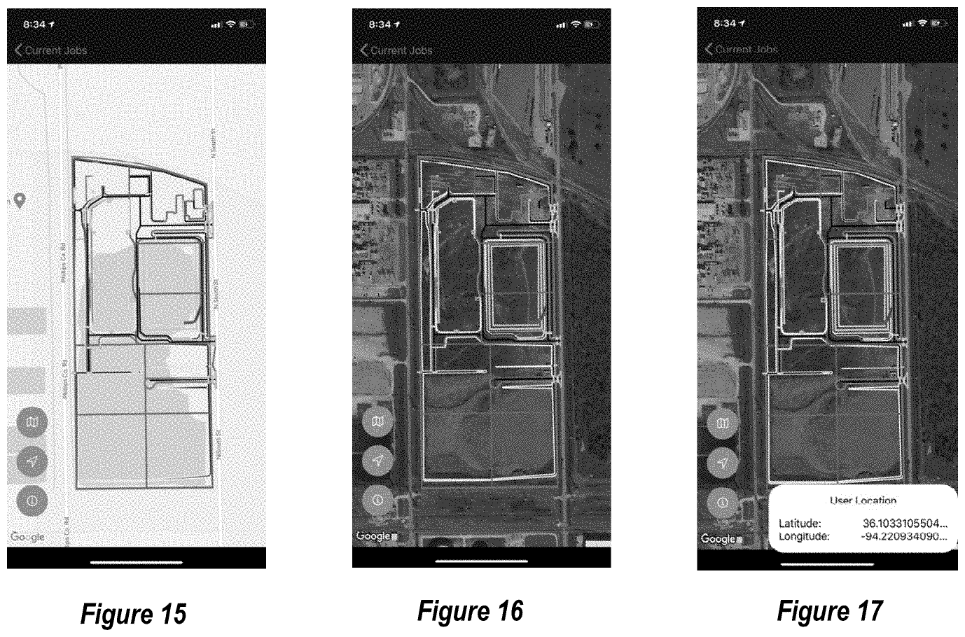

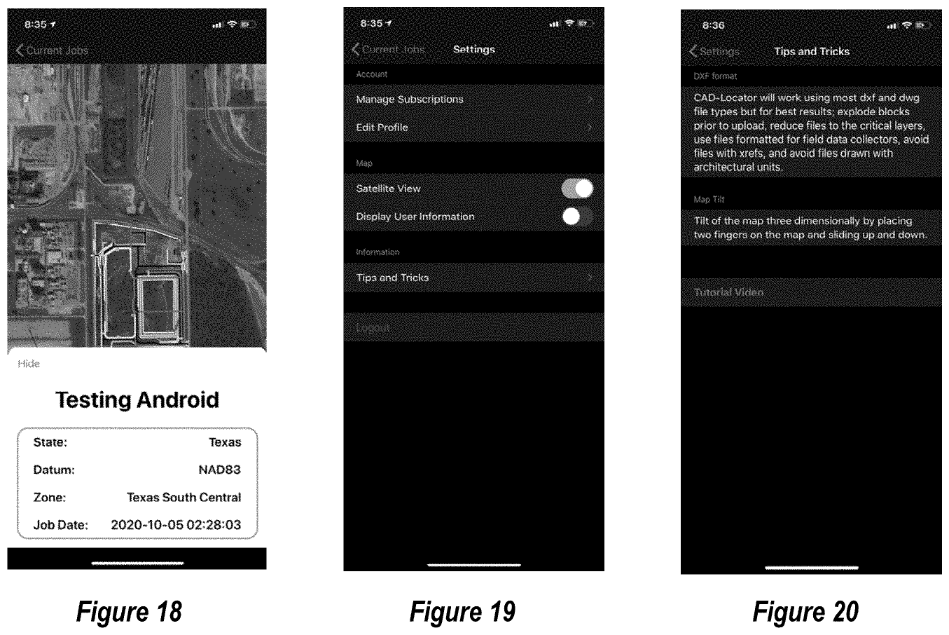

Referring now to FIG. 15, a rendered version of the overlay file 126 is shown overlaid on a basic location tracking enabled map 128. In FIG. 16, the rendered version of the overlay file 126 is illustrated overlaid on a satellite view of the location tracking enabled map 128. As illustrated in FIG. 17, user location information can be displayed as latitude and longitude or as northing and easting. Typically, devices work natively with latitude and longitude, but some embodiments may include additional code to convert latitude and longitude to northing and easting. In the example illustrated, a toggle can be selected to select between the representations. As illustrated in FIG. 18, the user can interact with the user interface to cause job information to be displayed in the app 116 user interface.

FIG. 19 illustrates additional settings that can be set in the app 116. For example, in FIG. 19, a user can manage subscriptions for accessing the services of the server 120 and/or permissions to use the app 116. FIG. 19 further illustrates that a user can edit their profile with respect to their account for using the app 116 and the services of the server 120. FIG. 19 further illustrates that a user can select between a satellite view and a non-satellite view for the location tracking enabled map 128. Thus, for example, the user can select between the views shown in FIGS. 15 and 16. FIG. 19 further illustrates that a user can use the interface to select between displaying user information or not displaying user information. For example, a user could select between the view illustrated in FIG. 16 and FIG. 17. As illustrated in FIG. 19, a user can also access additional information and help tips for using the app 116. For example, the user can interact with the user interface to obtain information such as that illustrated in FIG. 20 that can help the user more accurately and usefully use the app 116.

The following discussion now refers to a number of methods and method acts that may be performed. Although the method acts may be discussed in a certain order or illustrated in a flow chart as occurring in a particular order, no particular ordering is required unless specifically stated, or required because an act is dependent on another act being completed prior to the act being performed.

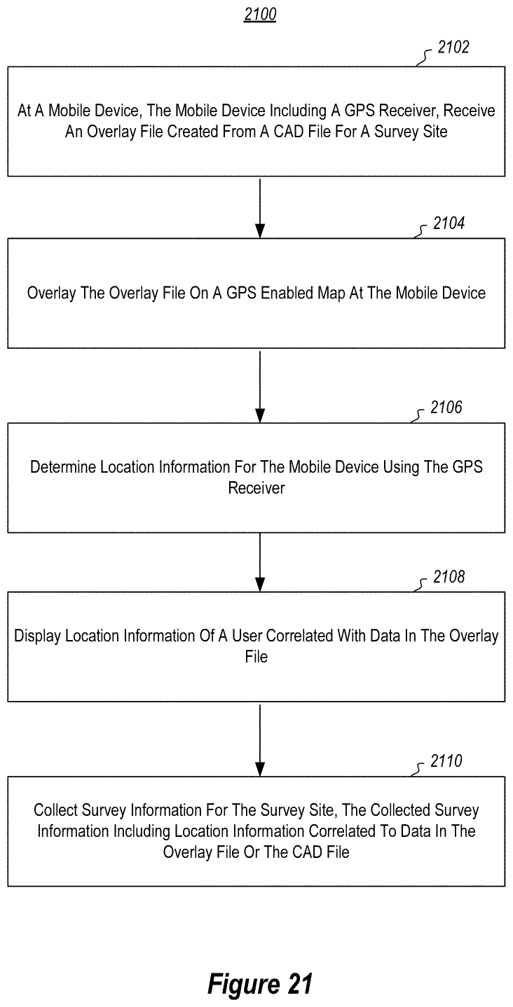

Referring now to FIG. 21, a method 2100 is illustrated. The method 2100 includes acts for collecting survey data for a survey site. The method 2100 includes at a mobile device, the mobile device including location tracking hardware, receiving an overlay file created from a CAD file for the survey site (act 2102). For example, FIG. 1 illustrates the cellular telephone 114 receiving the overlay file 126 from the server 120.

The method 2100 further includes overlaying the overlay file on a location tracking enabled map at the mobile device (act 2104). For example, FIG. 2 illustrates the overlay file being overlaid on the location tracking enabled map 128.

The method 2100 further includes determining location information for the mobile device using the location tracking hardware (act 2106). For example, as illustrated in FIG. 2, a user's location can be determined using the GPS hardware 130 and the location tracking enabled map 128. Note that in other embodiments, other location tracking hardware such as hardware that tracks pings from cell towers, hardware for detecting wi-fi networks having a known location, hardware for RFID tracking, etc. can be used.

The method 2100 further includes displaying location information of a user correlated with data in the overlay file (act 2108). For example, as illustrated in FIG. 2, location information can be displayed in the location tracking enabled map 128 and on the overlay file 126. See also the example illustrated in FIG. 17.

The method 2100 further includes collecting survey information for the survey site, the collected survey information including location information correlated to data in the overlay file or the CAD file (act 2110). For example, survey data can be collected in the data collector 134.

The method 2100 may be practiced where the location information comprises a location indicator on the location tracking enabled map.

The method 2100 may be practiced where the location information comprises latitude and longitude information. An example of this is illustrated at FIG. 17.

The method 2100 may further include converting latitude and longitude information from the location tracking enabled map to northing and easting coordinates and wherein the location information comprises the northing and easting coordinates.

The method 2100 may further include receiving the CAD file at the mobile device and sending the CAD file to a server, and where the overlay file is received from the server as a result of the server converting the CAD file to the overlay file. For example, FIG. 1 illustrates that the CAD file 110 is received from the computer system 108 at the cellular telephone 114 and sent from there to the server 120.

Further, the methods may be practiced by a computer system including one or more processors and computer-readable media such as computer memory. In particular, the computer memory may store computer-executable instructions that when executed by one or more processors cause various functions to be performed, such as the acts recited in the embodiments.

Embodiments of the present invention may comprise or utilize a special purpose or general-purpose computer including computer hardware, as discussed in greater detail below. Embodiments within the scope of the present invention also include physical and other computer-readable media for carrying or storing computer-executable instructions and/or data structures. Such computer-readable media can be any available media that can be accessed by a general purpose or special purpose computer system. Computer-readable media that store computer-executable instructions are physical storage media. Computer-readable media that carry computer-executable instructions are transmission media. Thus, by way of example, and not limitation, embodiments of the invention can comprise at least two distinctly different kinds of computer-readable media: physical computer-readable storage media and transmission computer-readable media.

Physical computer-readable storage media includes RAM, ROM, EEPROM, CD-ROM or other optical disk storage (such as CDs, DVDs, etc.), magnetic disk storage or other magnetic storage devices, or any other medium which can be used to store desired program code means in the form of computer-executable instructions or data structures and which can be accessed by a general purpose or special purpose computer.

A “network” is defined as one or more data links that enable the transport of electronic data between computer systems and/or modules and/or other electronic devices. When information is transferred or provided over a network or another communications connection (either hardwired, wireless, or a combination of hardwired or wireless) to a computer, the computer properly views the connection as a transmission medium. Transmission media can include a network and/or data links which can be used to carry desired program code means in the form of computer-executable instructions or data structures and which can be accessed by a general purpose or special purpose computer. Combinations of the above are also included within the scope of computer-readable media.

Further, upon reaching various computer system components, program code means in the form of computer-executable instructions or data structures can be transferred automatically from transmission computer-readable media to physical computer-readable storage media (or vice versa). For example, computer-executable instructions or data structures received over a network or data link can be buffered in RAM within a network interface module (e.g., a “NIC”), and then eventually transferred to computer system RAM and/or to less volatile computer-readable physical storage media at a computer system. Thus, computer-readable physical storage media can be included in computer system components that also (or even primarily) utilize transmission media.

Computer-executable instructions comprise, for example, instructions and data which cause a general-purpose computer, special purpose computer, or special purpose processing device to perform a certain function or group of functions. The computer-executable instructions may be, for example, binaries, intermediate format instructions such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

Those skilled in the art will appreciate that the invention may be practiced in network computing environments with many types of computer system configurations, including, personal computers, desktop computers, laptop computers, message processors, hand-held devices, multi-processor systems, microprocessor-based or programmable consumer electronics, network PCs, minicomputers, mainframe computers, mobile telephones, PDAs, pagers, routers, switches, and the like. The invention may also be practiced in distributed system environments where local and remote computer systems, which are linked (either by hardwired data links, wireless data links, or by a combination of hardwired and wireless data links) through a network, both perform tasks. In a distributed system environment, program modules may be located in both local and remote memory storage devices.

Alternatively, or in addition, the functionality described herein can be performed, at least in part, by one or more hardware logic components. For example, and without limitation, illustrative types of hardware logic components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc.

The present invention may be embodied in other specific forms without departing from its characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method of collecting survey data for a survey site, the method comprising:
at a mobile device, the mobile device including location tracking hardware, receiving an overlay file created from a CAD file for the survey site;
overlaying the overlay file on a location tracking enabled map at the mobile device;
determining location information for the mobile device using the location tracking hardware;
displaying location information of a user correlated with data in the overlay file; and
collecting survey information for the survey site, the collected survey information including location information correlated to data in the overlay file or the CAD file.

2. The method of claim 1, wherein the location information comprises a location indicator on the location tracking enabled map.

3. The method of claim 1, wherein the location information comprises latitude and longitude information.

4. The method of claim 1, further comprising converting latitude and longitude information from the location tracking enabled map to northing and easting coordinates and wherein the location information comprises the northing and easting coordinates.

5. The method of claim 1, further comprising receiving the CAD file at the mobile device and sending the CAD file to a server, wherein the overlay file is received from the server as a result of the server converting the CAD file to the overlay file.

6. A mobile device configured for collecting survey data for a survey site, the mobile device comprising:
location tracking hardware;
local storage storing an overlay file created from a CAD file for the survey site;
an app coupled to the local storage, wherein the app is configured to:
overlay the overlay file on a location tracking enabled map at the mobile device;
determine location information for the mobile device using the location tracking hardware;
display location information of a user correlated with data in the overlay file; and
collect survey information for the survey site, the collected survey information including location information correlated to data in the overlay file or the CAD file.

7. The mobile device of claim 6, wherein the location information comprises a location indicator on the location tracking enabled map.

8. The mobile device of claim 6, wherein the location information comprises latitude and longitude information.

9. The mobile device of claim 6, wherein the app is configured to convert latitude and longitude information from the location tracking enabled map to northing and easting coordinates and wherein the location information comprises the northing and easting coordinates.

10. The mobile device of claim 6, wherein the app is configured to access the CAD file at the mobile device and send the CAD file to a server, wherein the overlay file is received from the server as a result of the server converting the CAD file to the overlay file.

11. One or more hardware storage devices having stored thereon computer-executable instructions, the computer-executable instructions being executable by one or more processors of a computer system to cause the computer system to collect survey data for a survey site including causing the computer system to perform the following:
at a mobile device, the mobile device including location tracking hardware, receiving an overlay file created from a CAD file for the survey site;
overlaying the overlay file on a location tracking enabled map at the mobile device;
determining location information for the mobile device using the location tracking hardware;
displaying location information of a user correlated with data in the overlay file; and
collecting survey information for the survey site, the collected survey information including location information correlated to data in the overlay file or the CAD file.

12. The computer one or more hardware storage devices of claim 11, wherein the location information comprises a location indicator on the location tracking enabled map.

13. The computer one or more hardware storage devices of claim 11, wherein the location information comprises latitude and longitude information.

14. The computer one or more hardware storage devices of claim 11, the computer-executable instructions being executable by the one or more processors of the computer system to cause the computer system to convert latitude and longitude information from the location tracking enabled map to northing and easting coordinates and wherein the location information comprises the northing and easting coordinates.

15. The computer one or more hardware storage devices of claim 11, the computer-executable instructions being executable by the one or more processors of the computer system to cause the computer system to receive the CAD file at the mobile device and send the CAD file to a server, wherein the overlay file is received from the server as a result of the server converting the CAD file to the overlay file.
